(19) United States
(12) Patent Application Publication
(10) Pub. No.: US 2024/0193327 A1
(43) Pub. Date: Jun. 13, 2024

(54) DIGITAL TWINNING DATA SIMULATOR

(71) Applicant: Bank of America Corporation, Charlotte, NC (US)

(72) Inventors: George Albero, Charlotte, NC (US); Maharaj Mukherjee, Poughkeepsie, NY (US); William August Stahlhut, The Colony, TX (US)

(21) Appl. No.: 18/077,353

(22) Filed: Dec. 8, 2022

(51) Int. Cl. G06F 30/27

(52) U.S. Cl. CPC G06F 30/27

(57) ABSTRACT

Aspects of the disclosure relate to enhancing redundancy of computer systems. The disclosure provides a system architecture for maintaining operation of computer systems despite technical and infrastructure failures, such as a server going offline or losing network connections. The described architecture may include a digital twin that models the computer system. The digital twin may simulate evolution of data records and use the simulated data records to process computing tasks submitted to the unavailable computer system despite no access to the computer system.

### FIELD OF TECHNOLOGY

Aspects of the disclosure relate to enhancing redundancy of digital systems. Specifically, aspects of the disclosure relate to a system architecture for maintaining operation of digital systems despite technical and infrastructure failures.

### BACKGROUND OF THE DISCLOSURE

Computer systems play an integral role in the operations of nearly every enterprise across the globe. Large or small, enterprises rely on computer systems at all phases of their workflows. From communications and tracking to processing and record keeping, computer systems are the backbone of modern enterprises.

One critical weakness inherent in the reliance on computer systems may arise in a situation where a primary computer system is dependent on one or more connections to other secondary computer systems. For example, a primary computer system may link to a database or applications running on a remote server. In these situations, services provided by the primary computer system may be disrupted when a connection to those other linked systems is unavailable. Such a disruption may occur due to a malfunction with the connective elements, or an external factor such as a natural disaster that damages the connectivity infrastructure of the primary computer system. A loss of connection to the other secondary computer systems may prevent the primary computer system from effectuating accurate updates, processing computing tasks and provisioning data.

Conventionally, highly resilient systems provide a redundant infrastructure that can be switched on when the primary computer system experiences performance problems or any other failures. Computer systems with more than 99% uptime are considered “fault tolerant.” As the availability percentage approaches 100%, the more expensive it becomes to maintain availability. A difference in cost for 99.9% uptime (“fault tolerance”) versus 99.9999% uptime (“high availability”) can be substantial.

The costs for increased resiliency are even higher for computer systems that operate in complex enterprise environments. Large enterprise organizations may utilize over 4,000 different software applications. Access to the different software applications may be controlled by a network of over 4, 500 different computer servers. The large number of interconnected computer systems and associated software applications give rise to complex network environments and increased costs to maintain resiliency.

Conventional methods for increased resiliency include backup hardware. For example, a redundant array of independent disks (RAID) may provide resilient data storage solutions. Uninterruptible power supplies and generators may provide consistent and reliable power supply. Clustering is a process of linking a large number of computer servers. Overall, clustering may achieve continuous, or 100% uptime. However, clustering requires a relatively large number of duplicative computer systems to achieve the goal of 100% uptime. In addition to significant hardware costs, clustering requires additional software that allows the duplicative computer system, although physically distinct, to operate as a single logical system.

It would be desirable to provide systems and methods for high availability complex computer systems. It would also be desirable to maintain high availability of complex computer systems without high costs associated with the purchase and maintenance of duplicative hardware and software. It is therefore desirable to provide apparatus and methods for a DIGITAL TWINNING DATA SIMULATOR.

### BRIEF DESCRIPTION OF THE DRAWINGS

The objects and advantages of the disclosure will be apparent upon consideration of the following detailed description, taken in conjunction with the accompanying drawings, in which like reference characters refer to like parts throughout, and in which:

FIG. 1 shows an illustrative system in accordance with principles of the disclosure;

FIG. 2 shows an illustrative system and scenario in accordance with principles of the disclosure;

FIG. 3 shows illustrative processes in accordance with principles of the disclosure;

FIG. 4 shows operation of an illustrative system in accordance with principles of the disclosure;

FIG. 5 shows an illustrative system and scenario in accordance with principles of the disclosure;

FIG. 6 shows an illustrative system in accordance with principles of the disclosure; and

FIG. 7 shows an illustrative process in accordance with principles of the disclosure.

### DETAILED DESCRIPTION

Systems and methods for a redundant technology infrastructure are provided. The infrastructure may include a primary computer system. The infrastructure may include one or more secondary computer systems. The infrastructure may include three or more computer systems. Each computer system may include one or more computer servers. A computer server may be connected to a network. A computer server, as disclosed herein, may include a processor circuit. The processor circuit may control overall operation of the computer server and its associated components. The processor circuit may include hardware, such as one or more integrated circuits that form a chipset. The hardware may include digital or analog logic circuitry configured to perform any suitable (e.g., logical) operation.

A computer server may include one or more of the following hardware components: I/O circuitry, which may include a transmitter device and a receiver device and may interface with fiber optic cable, coaxial cable, telephone lines, wireless devices, physical network layer hardware, a keypad/display control device or any other suitable encoded media or devices; peripheral devices, which may include counter timers, real-time timers, power-on reset generators or any other suitable peripheral devices; a logical processing device, which may compute data structural information, structural parameters of the data, or quantify indices; and machine-readable memory.

Machine-readable memory may be configured to store, in machine-readable data structures: machine learning algorithms or any other suitable information or data structures. Components of the computer server may be linked by a system bus, wirelessly or by other suitable interconnections. System components may be present on one or more circuit boards. In some embodiments, the components may be integrated into a single chip. The chip may be silicon-based.

The server may include RAM, ROM, an input/output (“I/O”) module and a non-transitory or non-volatile memory. The I/O module may include a microphone, button and/or touch screen which may accept user-provided input. The I/O module may include one or more speakers for providing audio output and a video display for providing textual, audiovisual and/or graphical output.

A computer server may utilize computer-executable instructions, such as one or more software applications, executed by a processor. Software applications may provide instructions to the processor that enable the computer server to perform various functions. Exemplary software applications include an operating system, application programs, and an associated database.

Software applications may be stored within the non-transitory memory and/or other storage medium. Some or all of the computer executable instructions of the computer server may be embodied in hardware or firmware components of the server. Generally, software applications include routines, programs, objects, components, data structures, etc. that perform particular tasks or implement abstract data types.

Software application programs, which may be used by the computer server, may include computer executable instructions for invoking user functionality related to communication, such as email, short message service (“SMS”), and voice input and speech recognition applications. Software application programs may utilize one or more algorithms that formulate predictive machine responses, formulate database queries, process user inputs, process agent inputs, or any other suitable computing tasks.

The software applications may include an artificial intelligence (“AI”) engine. The AI engine may perform machine learning AI and deep machine learning AI. Machine learning AI may identify patterns in data sets and make decisions based on the detected patterns. Machine learning AI is typically used to predict future behavior. Machine learning AI improves each time the AI system receives new data because new patterns may be discovered in the larger data set now available to the machine learning AI. Deep machine learning AI adapts when exposed to different patterns of data. Deep machine learning AI may uncover features or patterns in data that the deep machine learning AI was never specifically programmed to find.

The AI engine may utilize one or more machine learning algorithms. The machine learning algorithms may identify usage patterns of hardware or software included in a primary computer system. The machine learning algorithms may generate models that reflect usage of hardware or software on the primary computer system. Machine learning algorithms improve over time because the algorithms are programmed to learn from previous decisions. Illustrative machine learning algorithms may include AdaBoost, Naive Bayes, Support Vector Machine and Random Forests. An illustrative machine learning algorithm may include a neural network such as Artificial Neural Networks and Convolutional Neural Networks.

Generally, a neural network implements machine learning by passing an input through a network of neurons—called layers—and providing an output. The more layers of neurons that are included in the neural network, the “deeper” the neural network. A neural network learns from outputs flagged as erroneous and adapts its neuron connections such that the next time the neural network receives a particular input it generates a more relevant output.

To effectively provide relevant outputs, a neural network must first be trained by analyzing training data sets. An illustrative data set may include computational tasks performed by the primary computer system over a target time period. Neural networks learn from the training data sets and rearrange interconnection between layers of the network in response to processing the training data. The strength or weight ofa connection between layers of the neural network can vary. A connection between two or more layers can be strong, weak or anywhere in between. A neural network may self-adapt by adjusting the strength of the connections among its layers to generate more accurate outputs.

A computer server may include a communication circuit. The communication circuit may include a network interface card or adapter. When used in a WAN networking environment, apparatus may include a modem, antenna or other circuitry for establishing communications over a WAN, such as the Internet. The communication circuit may include a modem and/or antenna. The existence of any of various well-known protocols such as TCP/IP, Ethernet, FTP, HTTP and the like is presumed, and the computer server may be operated in a client-server configuration to permit retrieval of web pages from a web-based server. Web browsers can be used to display and manipulate data on web pages.

A computer server may include various other components, such as a display, battery, speaker, and antennas. Network connected systems may be portable devices such as a laptop, tablet, smartphone, other “smart” devices (e.g., watches, eyeglasses, clothing having embedded electronic circuitry) or any other suitable device for receiving, storing, transmitting and/or displaying electronic information.

A computer server may include, and may be operational with, numerous other general purpose or special purpose computing system environments or configurations. Examples of well-known computing systems, environments, and/or configurations that may be suitable for use with this disclosure include, but are not limited to, personal computers, server computers, handheld or laptop devices, tablets, “smart” devices (e.g., watches, eyeglasses, clothing having embedded electronic circuitry) mobile phones, multiprocessor systems, minicomputer systems, microprocessor systems, mainframe computers, distributed computing environments that include any of the above systems or devices, and the like.

A computer server may be operational with distributed computing environments where tasks are performed by remote processing devices that are linked through a communications network. In a distributed computing environment, program modules may be located in both local and remote computer storage media, including memory storage devices. A computer server may rely on a network of remote servers hosted on the Internet to store, manage, and process data (e.g., “cloud computing” and/or “fog computing”).

A computer server disclosed herein may be produced by different manufacturers. For example, using a personal mobile device, a user may connect to a computer server hosting an automated chatbot system via a first computer server. The chatbot that processes the user's inputs may be run on a second computer server. A human agent may utilize a third computer server that provides a user interface for the agent to interact with the user and/or the chatbot.

The computer server may include cloud computing and virtualization implementations of software. Such implementations may be designed to run on a physical server supplied externally by a hosting provider, a client, or any other virtualized platform.

Computer servers may capture data in different formats. Computer servers may use different data structures to store captured data. Computer servers may utilize different communication protocols to transmit captured data or communicate with other systems. Despite such operational differences, computer servers may be configured to operate substantially seamlessly across different computer systems, operating systems, hardware or networks.

A redundant technology infrastructure disclosed herein may include a physical-virtual connection (“P-V connection”). The P-V connection may link a primary computer system to an AI engine. The P-V connection may provide the AI engine with performance metrics captured from the primary computer system. The captured performance metrics may provide a data set that allows machine learning algorithms executed by the AI engine to generate a digital twin of the primary computer system. A digital twin may refer to a virtual representation of the primary computer system.

A digital twin may be a virtual, software-based representation that serves as the real-time digital counterpart of the primary computer system. In the case of a technology infrastructure a digital twin may be used to simulate, validate, and/or understand different applications running on the primary computer system and their dependencies when running different components such as processors, memory cores, cloud services, load balancers, web servers, database servers, network servers, etc.

The P-V connection may include a plurality of edge nodes. The P-V connection may include an application programming interface (“API”) for communicating with those edge-nodes. The P-V connection may be configured to communicate as if it was itself an edge-node. For example, edge-nodes may communicate directly with other edge-nodes using machine-to-machine (“M2M”) protocols over the P-V connection. Illustrative M2M protocols may include MQ Telemetry Transport (“MQTT”). M2M includes communication between two or more objects without requiring direct human intervention. M2M communications may include automated decision-making and communication processes.

The P-V connection may include a graphical user interface (GUI) for human users to interact with the digital twin. The GUI may display virtual components of the digital system and may display the virtual components as an interconnected graph comprising nodes and edges. The nodes may represent virtual components and the edges may represent associations between the virtual components in the digital twin. The GUI may also display performance metrics for each virtual component. The GUI may be configured to receive potential modifications for each virtual component.

The AI engine may construct the digital twin by simulating digital representations of hardware and software associated with the primary computer system. A digital twin may generally be a virtual, software-based representation that serves as the real-time digital counterpart of the primary computer system. As part of a redundant technology infrastructure, the digital twin may be used to simulate, validate, and/or understand different applications and their dependencies when running different components such as processors, memory cores, cloud services, load balancers, web servers, database servers, network servers, etc.

To create the digital twin, the AI engine may capture state information from the primary computer system. The state information may include any suitable information regarding operation of the primary computer system. For example, the state information may include performance metrics associated with operation of hardware and software components of the primary computer system. The AI engine may store a list of hardware and software components in operation on the primary computer system. The AI engine may also be configured to detect, via a plurality of edge-node sensors, performance metrics of the hardware and software components of the primary computer system.

The hardware and software components may be components that are initially installed with the primary computer system. These may be ‘off-the-shelf’ components that may typically be provided as a list when a system is initiated. This list may form a foundational basis upon which the digital twin may be modeled. To construct an accurate digital twin, however, it may be advantageous to also model performance metrics of the components associated with the primary computer system.

The state information may include hardware components of the primary computer system. One or more sensors may identify the hardware components. The sensors may track operation of the hardware components. The state information may include software components of the primary computer system. The state information may include performance metrics associated with interaction between the hardware and software components. Illustrative performance metrics may include power used by a processor when executing operating system requests.

Modeling the digital twin based on a comprehensive list of system components of the primary computer system and associated performance metrics may allow the AI engine to generate an accurate and effective model of the primary computer system. The AI engine may detect the system components and performance metrics using edge nodes to measure and analyze the primary computer system as it actually performs at runtime. The ongoing monitoring of the primary computer system may provide an up-to-date, accurate state information of the primary computer system that is gathered in a bottom-up manner based on actual system performance.

An edge-node may include one or more sensors. A sensor may detect changes in attributes of a physical or virtual operating environment. Each change may be state information provided to the AI engine. For example, sensors may measure attributes such as electronic network traffic, information processed, customer traffic, resource usage, electronic signals (e.g., input or output) or frequency of user logins. Contextually, the state information provides the AI engine with information not only about the native (physical or virtual) operating environment of the primary computer system, but data captured by multiple edge nodes may provide data that signifies occurrence an event such as initiation or completion of a computing task. The AI engine may apply analytical tools (e.g., big data analysis techniques) to detect, within the received state information, occurrence of an event that triggers the primary computer system to take a responsive action and how data stored within the primary computer system changes in response to those events.

Edge nodes may include System-on-a-Chip (“SOC”) architecture and may be powerful enough to run operating systems and complex data analysis algorithms. An illustrative SoC may include a central processing unit (“CPU”), a graphics processor (“GPU”), memory, power management circuits, and communication circuits. Edge-nodes may control other edge-nodes. Edge-nodes, or the nodes they control, may not be continuously connected to a network. Edge-nodes may provide computational resources positioned near the source of captured data or near an operating environment. Processing data using edge-nodes may reduce the communication bandwidth needed to transmit data from an edge node to the AI engine.

In addition to providing faster response time to sensed changes, processing data using edge-nodes may reduce communication bandwidth requirements and improve overall data transfer time across a network in which they operate. Furthermore, less frequent data transmissions may enhance security of data gathered by edge nodes. Frequent data transfers may expose more data to more potential security threats. For example, transmitted data may be vulnerable to being intercepted enroute to the AI engine. Additionally, edge-nodes may be tasked with decision-making capabilities. Edge-nodes may identify and discard non-essential data. Such disregarded data may never be transmitted or stored in the AI engine, further reducing network bandwidth consumption and exposure of such data to security threats.

State information captured by edge nodes in an operating environment of the primary computer system may be voluminous and complex (e.g., structured/unstructured and/or constantly changing). Traditional data processing application software may be inadequate to meaningfully process the voluminous and complex data (e.g., “big data”). The AI engine may employ software applications specially designed to process large volumes of state information (“big data analytics”).

A digital twin constructed by the AI engine may replicate and simulate performance of the hardware and software components of the primary computer system. The digital twin may be configured to simulate performance of the primary computer system. Unconventionally, the digital twin may be configured to simulate generation of data or records based on state information processed by the AI engine. The digital twin may utilize the received state information to determine how the primary computer system data would have processed a computing task. The AI engine may simulate the evolution of state information captured from the primary computer system while the primary computer system is offline.

The AI engine may apply machine learning algorithms that detect patterns indicating how the captured state information would evolve and how the state information used to build the digital twin would change while the primary computer remains offline. For example, the machine learning algorithms may detect patterns within financial data. Exemplary patterns may indicate that $10,000 in deposits posts to an account by the third day of a month. Based on this pattern, the digital twin, even when the primary computer system is offline, the digital twin may increase the last recorded balance by $10,000 on the third day of a new month. The digital twin may approve transactions that rely on the expected deposit of $10,000, even when a live connection to the primary computer system is unavailable.

The edge-nodes may provide sensed state information captured from the primary computer system to the AI engine via the P-V connection. The P-V connection may support a variety of communication protocols. Illustrative supported protocols may include HyperText Transfer Protocol (“HTTP”), Simple Object Access Protocol (“SOAP”), REpresentational State Transfer (“REST”) Constrained Application Protocol (“CoAP”), SensorML, Institute of Electrical and Electronic Engineers (“IEEE”) 802.15.4 (“ZigBee”) based protocols, IEEE 802.11 based protocols. For example, ZigBee is particularly useful for low-power transmission and requires approximately 20 to 60 milli-watts (“mW”) of power to provide 1 mW transmission power over a range of 10 to 100 meters and a data transmission rate of 250 kilobits/second.

Other exemplary wireless communication protocols may include Ethernet, Bluetooth, Wi-Fi, 3G, 4G, 5G and any other suitable wired or wireless broadband standards. The P-V connection may include hardware and/or software for receiving and/or transmitting data using any suitable communication pathway. Illustrative communication pathways utilized by the P-V connection may include Wi-Fi, wired connections, Bluetooth, cellular networks, satellite links, radio waves, fiber optic or any other suitable medium for carrying signals.

Based on data provided to the AI engine over the P-V connection, the AI engine may detect that the primary computer system is offline. “Offline” may refer to a computer system that is not controllable or directly connected to another computer or external network. For example, the AI engine may detect that the primary computer system is not responding to processing requests submitted via a network or by other computer systems. The AI engine may detect that edge-nodes are no longer capturing state information from the primary computer system.

In response to detecting that the primary computer system is offline, the AI engine may activate the digital twin to process computing tasks on behalf of the primary computer system. Activating the digital twin to process computing tasks may include directing all computing tasks destined for processing by the primary computer system to the digital twin. The digital twin may receive the computing tasks using the P-V connection.

The digital twin may generate an output in response to a received computing task. The digital twin may generate the output using simulated data generated based on the state information. The digital twin may generate the output based on simulating evolution of state information received from the primary computer system prior to going offline. The digital twin may process service requests, update records and trigger any suitable action based on simulating evolution of the state information. The digital twin may communicate the generated output to a requesting computer system using the P-V connection.

The digital twin may compute a threshold fidelity level for the simulated data. The threshold fidelity level may be computed based on the captured state information used by the AI engine to construct the digital twin. The threshold fidelity level may determine when the simulated evolution of the state information will be outdated for a given requested computing task submitted to the digital twin. The threshold fidelity level may be independently computed for each possible computing task that may be submitted to the digital twin. The threshold fidelity level may be independently computed for each element of state information that is simulated by the digital twin.

For example, if the state information indicates that a first user account is associated with a relatively high number of daily transactions, the fidelity level may occur earlier than for a second user account that is associated with a lower number of daily transactions. A service request such as an account balance may be associated with a different fidelity level than an account transfer request.

In addition to the evolution of the state information, the fidelity level may be determined based on a time the primary computer system went offline. The fidelity level may progressively decrease the longer the primary computer system remains offline. The fidelity level may decrease at different rates for different computing tasks such as service actions or requests. For some computing tasks, the fidelity level may decrease exponentially. For other computing tasks, the fidelity level may decrease linearly.

After simulated state information falls below a threshold fidelity level, the AI engine may reject a second computing task addressed to the primary computer system. The AI engine may determine that for the second computing task, the digital twin will not provide an accurate or precise response.

The AI engine may determine a twinning rate. The information twinning rate may control a sampling rate state captured from the primary computer system. The twinning rate may refer to how often sensors capture state information from components of the primary computer system. The twinning rate may determine how frequently the AI engine obtains state information from the primary computer system used to build the digital twin.

The twinning rate may be determined based on performance metrics computed by the AI engine. The performance metrics may indicate how often data or other components change within the primary computer system. A higher twinning rate may correspond to a higher sampling rate that provides more data points than a lower twinning rate. A higher twinning rate may allow the AI engine and associated machine learning algorithms to detect nuanced patterns within captured state information.

For example, the AI engine may apply machine learning algorithms to captured state information that includes financial data. Exemplary financial data may include account balances, bill pay activity and deposits. A higher twinning rate may capture hourly changes in the financial data. A lower twinning rate may only capture daily changes in the financial data. The AI engine may apply machine learning algorithms to historical data stored on the primary computer system. The machine learning algorithms may determine an appropriate twinning rate based on patterns detected in the historical data stored on the primary computer system.

The AI engine may detect that the primary computer system is back online after having been offline. Using the P-V connection, the AI engine may synchronize the primary computer system based on computing tasks processed by the digital twin while the primary computer system was offline. For example, the digital twin may synchronize the primary computer system with transactions that have been approved or denied by the digital twin while the primary computer system was offline. The synchronized information provided by the digital twin may itself be included in future state information captured by the AI engine to build or update a digital twin.

In some embodiments, the primary computer system may be capable of receiving requests to process a computing task. However, the primary computer system may not be able to connect with a cloud computing environment or access software or hardware resources needed to process the computing task. The primary computer system may receive the computing task and redirect the computing task to the digital twin using the P-V connection.

The digital twin may then process the computing task. The digital twin may be capable of simulating functionality of the cloud computing environment or inaccessible software/hardware resources needed to process the computing task. The digital twin may provide the processing result to the primary computer system which may then provide the result to the requesting system. The digital twin may provide the processing result directly to the requesting system.

The digital twin may compute, based on received state information, a threshold fidelity level for a first subset of simulated data required to process a first computing task. Based on a time the primary computer system went offline, the digital twin may determine when the first subset of the simulated data will fall below the threshold fidelity level. After the first subset of simulated data is scheduled to fall below the threshold fidelity level, the digital twin may reject a second computing task that also requires the first subset of the simulated data to process the second computing task.

The digital twin may reject the second computing task because the first subset of the simulated data needed to process the second computing task may be stale or out-of-date and therefore unreliable for processing the second computing task. However, the digital twin may process a third computing task that requires a second subset of the simulated data to process the third computing task. The second subset of the simulated data may be above a threshold fidelity level even if the first subset of the simulated data is not. For example, the first set of simulated data may change more frequently than the second set of simulated data needed to process the third computing task. Thus, the first set of simulated data may fall below a threshold fidelity level sooner after the primary computer system goes offline.

A redundant technology infrastructure is provided. The infrastructure may include a primary computer system. The infrastructure may include a physical-virtual (“P-V”) connection. The infrastructure may include an artificial intelligence (“AI”) engine. The AI engine may be configured to capture first state information from the primary computer system using the P-V connection. The AI engine may construct a first digital twin of the primary computer system based on the captured first state information.

The AI engine may determine a threshold fidelity level for the first digital twin. The threshold fidelity level may be determined based on when the AI engine last received state information from the primary computer system. The AI engine may determine a target time when the first digital twin will fall below the threshold fidelity level. Before the target time, the AI engine may construct a second digital twin based on second state information captured using the P-V connection. The second digital twin may be configured to fall below the threshold fidelity level after the target time.

The second state information may be captured from the primary computer system at a different twinning rate compared to the first state information. The AI engine may construct the first digital twin based on capturing state information from the primary computer system at a first twinning rate. The AI engine may construct the second digital twin based on capturing state information from the primary computer system at a second twinning rate.

The AI engine may detect that the primary computer system is offline. The AI engine may instruct one or more edge-nodes to divert computing tasks destined for the primary computer system to the first digital twin. An edge-node may divert a computing task to the first digital twin. In some embodiments, the edge-node itself may detect that the primary computer system is offline. In response to receiving a computing task directed to the primary computer system, the edge-node may redirect the computing task to the first digital twin. The first digital twin may process the computing task received from the edge-node and generate a response to the computing task. The AI engine may provide the response to the edge-node using P-V connection.

The AI engine may receive a plurality of computing tasks addressed to the primary computer system. The AI engine may receive the plurality of computing tasks from one or more edge-nodes. The AI engine may divert the plurality of computing tasks to the first digital twin. The AI engine may process the plurality of computing tasks using the first digital twin.

The AI engine may generate performance metrics based on the processing of the plurality of computing tasks by the first digital twin. Based on the performance metrics, the AI engine may proactively take the primary computer system offline. For example, the performance metrics may indicate that one or more components of the primary computer system are malfunctioning or may imminently malfunction. The performance metrics may indicate that the primary computer system is processing computing tasks at a slower rate than usual. The AI engine may proactively take the primary computer system offline and redirect computing tasks to the first digital twin. While the first digital twin is processing the redirected computing tasks, the malfunction or expected malfunction associated with the primary computer system may be repaired.

The infrastructure may include a plurality of edge-nodes. Each edge-node may include a sensor that captures state information such as performance metrics of a hardware and/or software component of the primary computer system. Illustrative performance metrics may include: memory utilization, central processing unit (CPU) utilization, CPU heat level, disk swap, processing speed, and transmission latency. The captured performance metrics may indicate a malfunction or imminent malfunction of a hardware and/or software component of the primary computer system.

A method for providing redundant computing processing in response to a technology infrastructure failure is provided. The method may include using a plurality of edge-nodes, capturing performance metrics associated with components of a primary computer system. The methods may include constructing a digital twin of the primary computer system based on the captured performance metrics.

The methods may include detecting that the primary computer system is offline. The methods may include, for a target duration after detecting that the primary computer system is offline, redirecting one or more computing tasks addressed to the primary computer system to the digital twin.

The methods may include using the digital twin to generate a response to the computing task based on simulated data generated by the digital twin. The target duration may correspond to a period of time starting from detecting that the primary computer system is offline and ending when the simulated data is expected to fall below a threshold fidelity level.

An AI engine may implement the digital twin. The AI engine may include a computer system that executes one or more machine learning algorithms that generate response to computing task based on an expected evolution of state information received from the primary computer system. The AI engine may predict how state information captured (e.g., by the edge-nodes) from the primary computer system will evolve, even without a live connection to the primary computer system.

The methods may include using the AI engine, computing a threshold fidelity level for simulated data generated by the digital twin. The AI engine may then generate responses to a requested computing task based on simulating evolution of the state information captured from the primary computer system. The AI engine may generate responses to a requested computing tasks based on a simulated evolutionary status of the captured state information at a time a computing task is received by the digital twin.

The methods may include detecting that the primary computer system is back online. The methods may include synchronizing one or more records stored on the primary computer system based on simulated evolution of state information captured from the primary computer system while the primary computer system was offline. For example, the methods may include updating records of the primary computer system based on the results of computing tasks processed by the digital twin while the primary computer system was offline.

Apparatus and methods in accordance with this disclosure will now be described in connection with the figures, which form a part hereof. The figures show illustrative features of apparatus and method steps in accordance with the principles of this disclosure. It is to be understood that other embodiments may be utilized, and that structural, functional and procedural modifications may be made without departing from the scope and spirit of the present disclosure.

The steps of methods may be performed in an order other than the order shown and/or described herein. Method embodiments may omit steps shown and/or described in connection with illustrative methods. Method embodiments may include steps that are neither shown nor described in connection with illustrative methods. Illustrative method steps may be combined. For example, an illustrative method may include steps shown in connection with any other illustrative method.

Apparatus may omit features shown and/or described in connection with illustrative apparatus. Apparatus embodiments may include features that are neither shown nor described in connection with illustrative apparatus. Features of illustrative apparatus may be combined. For example, an illustrative apparatus embodiment may include features shown or described in connection with another illustrative apparatus/method embodiment.

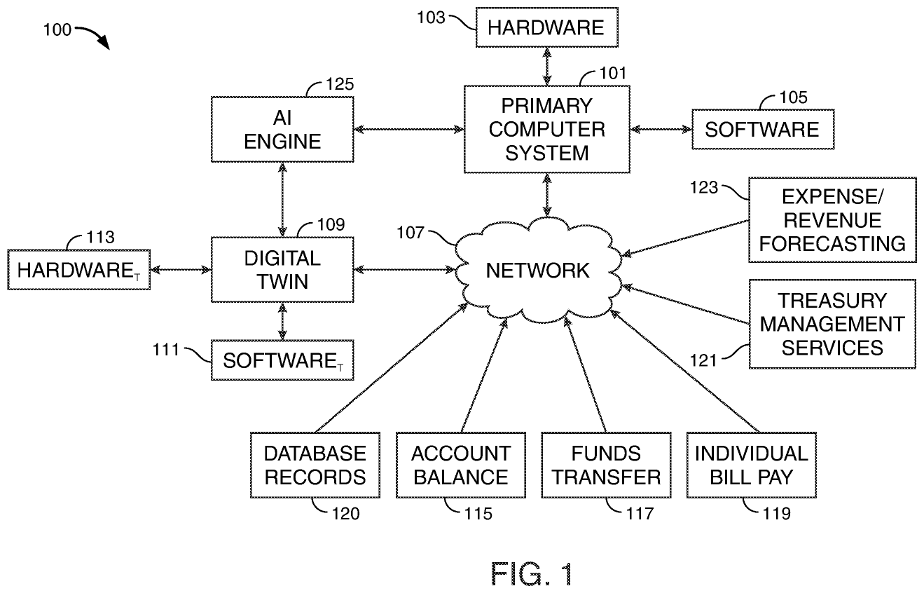

FIG. 1 shows illustrative system 100. System 100 includes primary computer system 101. Primary computer system 101 includes hardware components 103 and software components 105. Illustrative hardware components 103 may include a digital signal processor device, a microprocessor device, a GPU, and various analog to digital converters, digital to analog converters, RAM, ROM, touch screen, speakers, an Ethernet interface, or an antenna coupled to a transceiver configured to operate on wireless network. Illustrative software components 105 may include a database or database system, an operating system, API, graphical user interface, email application, word processor or other software-based productivity tools.

Network 107 may receive requests to process computing tasks. Illustrative computing tasks include account balance 115, funds transfer 117, individual bill pay service 119, access to and database records 120, treasury management services 121 expense/revenue forecasting 123.

AI engine 125 may monitor an operational status of primary computer system 101. Under typical operating conditions, network 107 routes requests for computing tasks to primary computer system 101 for processing. Also, under typical operating conditions, AI engine 125 may capture state information from primary computer system 101. The captured state information may include any suitable information regarding operation of the primary computer system.

For example, the captured state information may include performance metrics associated with operation of hardware components 101 and software components 105. Illustrative performance metrics may include memory utilization, central processing unit (CPU) utilization, graphics processing unit (GPU) utilization CPU heat level, disk swap, processing speed, and transmission latency associated with hardware components 103 and software components 105. AI engine 125 may employ software applications specially designed to process large volumes of state information (“big data analytics”).

AI engine 125 may construct digital twin 109 based on the captured state information. Digital twin 109 may be kept current based on an ongoing inflow of state information captured from primary computer system 101 by AI engine 125. Digital twin 109 may include “twinned” software components 111 and “twinned” hardware components 113. Software components 111 may simulate software components 105. Hardware components 113 may simulate hardware components 103.

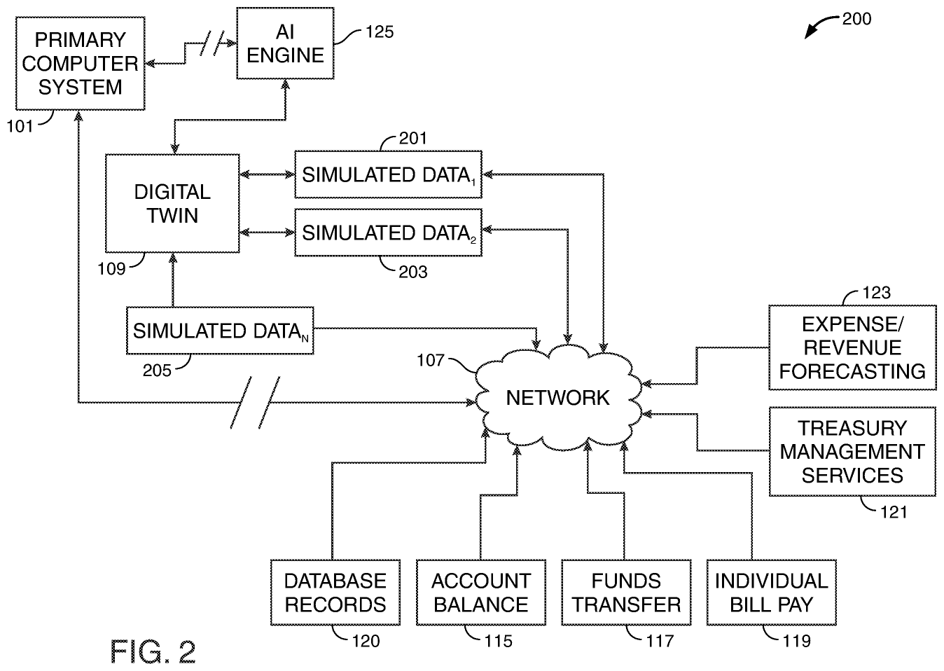

FIG. 2 shows illustrative operational scenario 200. In scenario 200, network 107 and AI engine 125 are unable to access primary computer system 101. AI engine 125 may determine that primary computer system 101 is offline. However, network 107 may continue to receive requests to process computing tasks, such as exemplary computing tasks 120, 115, 117, 119, 121 and 123. To process such computing tasks while primary computer system 101 is offline, the computing tasks received by network 107 may be redirected to digital twin 109.

While primary computer system 101 is offline, digital twin 109 may replicate and simulate performance of hardware components 103 (e.g., twinned hardware components 113) and software components 105 (e.g., twinned software components 111) of primary computer system 101. Even when primary computer system 101 is offline, AI engine 125 may use digital twin 109 (and the associated twinned hardware components 113 and twinned software components 111) to process computing tasks received by network 107

Even without an ongoing connection to primary computer system 101, using AI engine 125, digital twin 109 may simulate performance of primary computer system 101. Digital twin 109 may simulate generation and evolution of state information, including data records, captured from primary computer system 101. FIG. 2 shows that digital twin 109 may generate simulated data 201, 203 and 205. Digital twin 109 may use the simulated data to process computing tasks received from network 107 while primary computer system 101 remains offline.

Evolution of state information may determine how primary computer system 101 would have changed data records or other state information. While primary computer system 101 is offline, AI engine 125 may provide the software and hardware needed to simulate the evolution of state information captured from primary computer system 101 and stored within digital twin 109. AI engine 125 may apply machine learning algorithms that detect patterns indicating how captured state information would evolve had primary computer system 101 remained online and processed the computing tasks received from network 107 while primary computer system 101 is in fact offline.

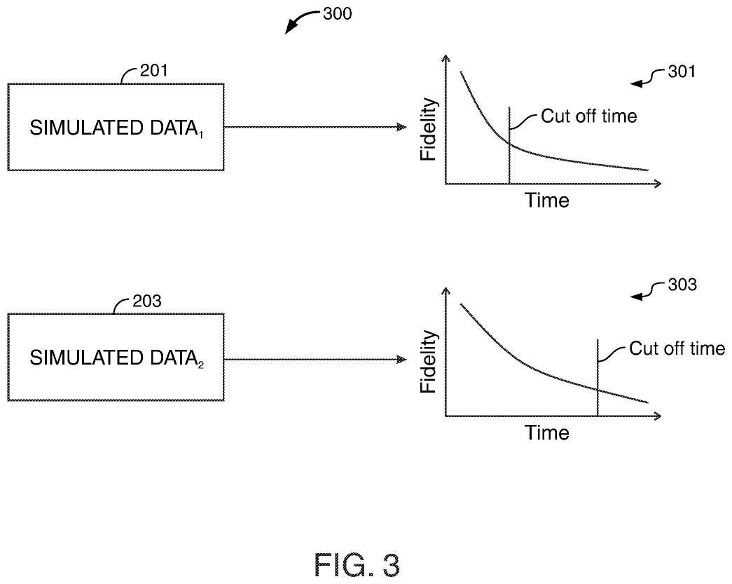

FIG. 3 shows illustrative process 300. Process 300 shows that simulated data 201 falls below a threshold fidelity level faster than simulated data 203. Simulated data 201 may be associated with performance metrics that indicate that it changes more rapidly than simulated data 203. Because simulated data 201 changes more rapidly than simulated data 203, absent an ongoing, live connection to primary computer system 101, simulated data 201 may fall below a threshold fidelity level faster than simulated data 203.

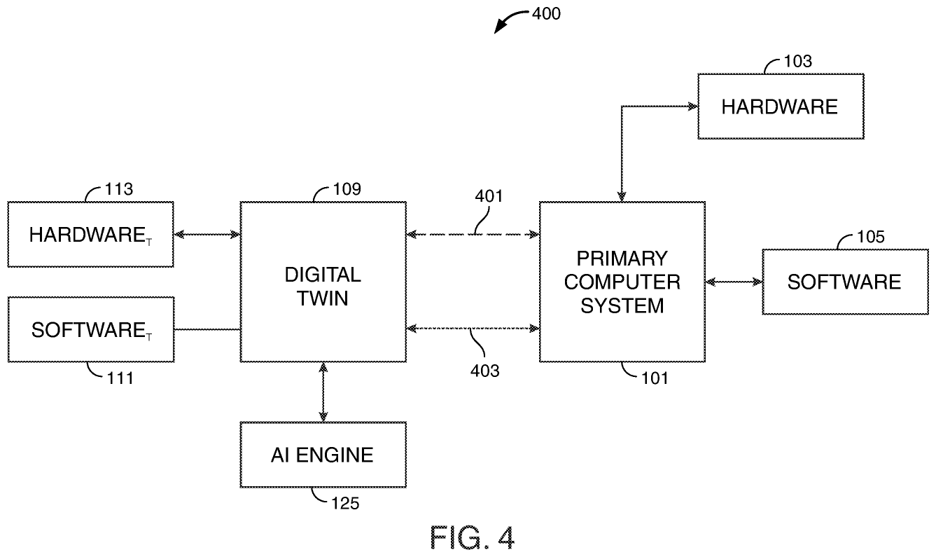

FIG. 4 shows operational scenario 400 of an illustrative system in accordance with this disclosure. Scenario 400 shows that digital twin 109 captures state information 401 and 403 from primary computer system 101. AI engine 125 may regulate the capture of state information 401 and 403. A P-V connection may be used to capture state information 401 and 403. AI engine 125 may capture state information 401 at a first twinning or sampling rate. AI engine 125 may capture state information 403 at a second twinning or sampling rate. A higher twinning or sampling rate may capture more data points than a lower twinning or sampling rate. Captured state information 401 and 403 may be used to build digital twin 109.

State information 401 may include performance metrics associated with hardware 103. State information 403 may include performance metrics associated with software 105. Performance metrics associated with hardware 103 may change less frequently than performance metrics associated with software 105. For example, software applications may be added, removed or updated more frequently than changes to a hardware profile associated with primary computer system 101. Therefore, to build digital twin 109, software 105 may be sampled by AI engine 125 at a higher twinning rate compared to hardware 103.

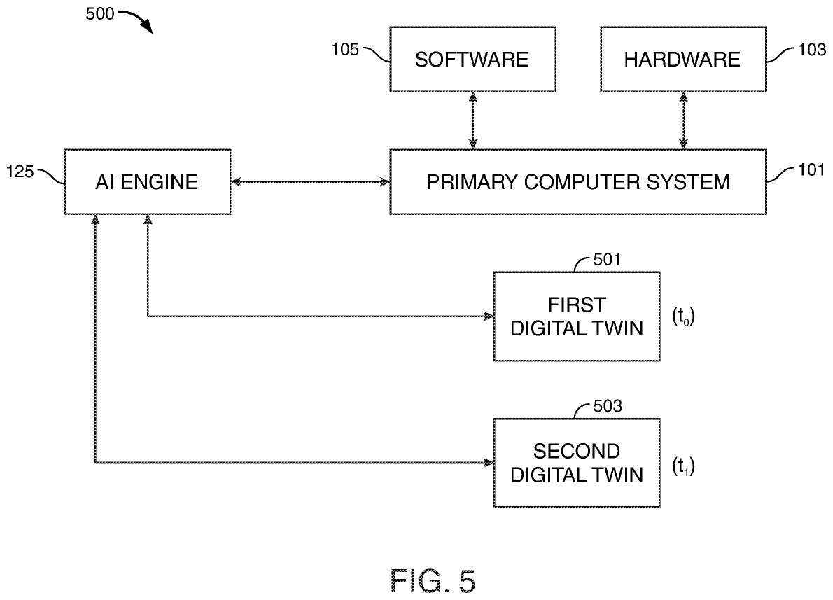

FIG. 5 shows illustrative system 500. System 500 includes digital twin 501 and digital twin 503. FIG. 5 shows that digital twin 501 is generated by AI engine 125 at to and digital twin 503 is generated by AI engine 125 later in time, at t₁. AI engine 125 may generate multiple digital twins at different times. Each digital twin generated by AI engine 125 may be configured to simulate different components of primary computer system 101.

Each digital twin generated by AI engine 125 may be associated with a snapshot of primary computer system 101 at different times (e.g., t₀ and t₁. Digital twin 501 may be associated with a first threshold fidelity level and digital twin 503 may be associated with a second threshold fidelity level. AI engine 125 may be configured to coordinate the generation of digital twins of primary computer system 101 such that should primary computer system 101 go offline, at least one digital twin will be available to process computing tasks on behalf of primary computer system 101 for a target duration at a threshold fidelity level.

For the entire target duration, the digital twin must be associated with a threshold fidelity level to process computing tasks on behalf of primary computer system 101. Therefore, after generating digital twin 501 at t₀, AI engine 125 may generate digital twin 503 at t₁ such that at least one of digital twin 501 or 503 will be available for the target duration and at the threshold fidelity level. In other embodiments, AI engine 125 may generate three or more digital twins to ensure that a digital twin will be available to process computing tasks on behalf of primary computer system 101 for a target duration at the threshold fidelity level.

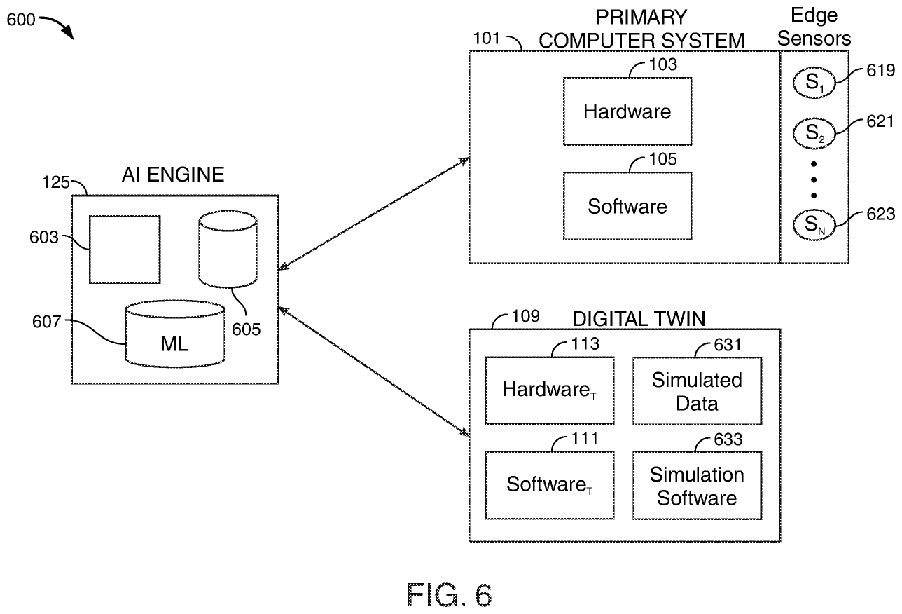

FIG. 6 shows illustrative system 600 for generating digital twin 109. AI engine 125 may generate digital twin 109 based on state information captured from primary computer system 101. FIG. 6 shows edge-nodes 619-623 that may be used to capture state information from primary computer system 101. Each of edge-nodes 619-623 may include hardware and/or software sensors positioned to monitor components of primary computer system 101. Each of edge-nodes 619-623 may detect the presence and/or performance metrics of components of primary computer system 101. Each of edge-nodes 619-623 may include sensing components such as thermometers, cameras, software modules, or any other suitable sensors.

AI engine 125 may process state information received from edge-nodes 619-623. AI engine 125 itself includes processor 603, memory 605, and ML algorithms 607. Digital twin 109 may include hardware 103 and software 105. Digital twin 109 may be completely software based. Digital twin 109 may include simulation software 633 that models operation of hardware 103 and software 105 running on primary computer system 101. Simulation software 633 may generate twinned hardware components 113 and twinned software components 111. Simulation software 633 may simulate interaction of twinned hardware components 113 and twinned software components 111. Simulation software 633 may generate simulated data records based on the simulated interaction of twinned hardware components 113 and twinned software components 111.

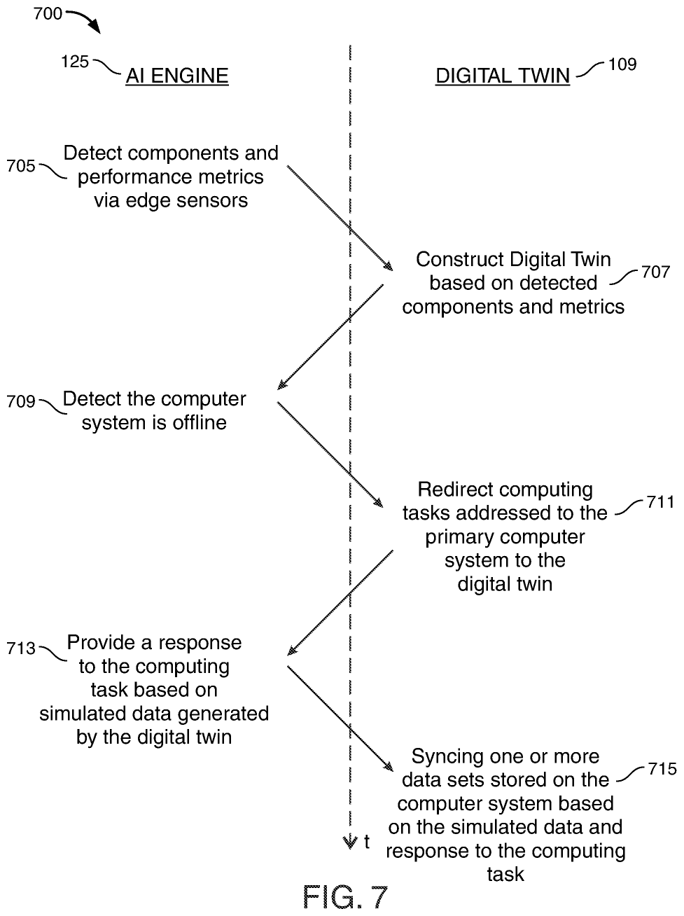

FIG. 7 shows illustrative process 700. FIG. 7 shows an illustrative process that may be implemented by AI engine 125 to capture state information from primary computer system 101 (shown in FIG. 1) and generate digital twin 109. Process 700 shows action taken by AI engine 125 and action taken by digital twin 109. A broken line represents the passage of time t.

Process 700 begins at step 705, where at least one edge-node detects components and performance metrics (e.g., state information) associated with primary computer system 101. At step 707, digital twin 109 is constructed based on the detected components and metrics. At step 709, AI engine 125 detects that primary computer system 101 is offline. At step 711, AI engine 125 redirects computing tasks addressed to primary computer system 101 to digital twin 109. Even without a live connection to the primary computer system 101, digital twin 109 may evolve and modify state information based on previously captured and computed performance metrics associated with primary computer system 101.

Digital twin 109 may only evolve and modify state information as long as the state information associated with digital twin 109 is at or above a threshold fidelity level. At step 713, AI engine 125 provides a response to a computing task based on simulated data generated by digital twin 109. At step 715, AI engine 125 may detect that primary computer system 101 is back online. AI engine 125 may synchronize one or more data sets stored on primary computer system 101 based on the simulated data and response to the computing tasks generated by digital twin 109.

Thus, apparatus and methods for a DIGITAL TWINNING DATA SIMULATOR are provided. Persons skilled in the art will appreciate that the present disclosure can be practiced by other than the described embodiments, which are presented for purposes of illustration rather than of limitation. The present disclosure is limited only by the claims that follow.

What is claimed is:

1. A redundant technology infrastructure comprising:
a primary computer system;
a physical-virtual connection; and
a digital twin of the primary computer system that:
receives state information from the primary computer system using the physical-virtual connection;
in response to detecting that the primary computer system is offline, generates an output to a computing task addressed to the primary computer system using simulated data generated based on the state information; and
communicates the output to a requesting computer system using the physical-virtual connection.

2. The redundant technology infrastructure of claim 1 wherein the computing task is a first computing task, the digital twin is further configured to:
compute, based on the state information, a threshold fidelity level for the simulated data;
based on a time the primary computer system went offline, determine when the simulated data will fall below the threshold fidelity level; and
after the simulated data falls below the threshold fidelity level, reject a second computing task addressed to the primary computer system.

3. The redundant technology infrastructure of claim 1 wherein the state information comprises:
hardware components of the primary computer system;
software components of the primary computer system; and
performance metrics associated with interaction between the hardware components and the software components.

4. The redundant technology infrastructure of claim 3 wherein the digital twin:
determines a twinning rate based on the performance metrics; and
regulates intake of the state information from the primary computer system based on the twinning rate.

5. The redundant technology infrastructure of claim 1 wherein the digital twin is configured to:
detect that the primary computer system is back online after having been offline; and
using the physical-virtual connection, synchronize the primary computer system based on performance of the digital twin while the primary computer system was offline.

6. The redundant technology infrastructure of claim 1 wherein the state information comprises a synchronization of the primary computer system based on the performance of the digital twin while the primary computer system was offline.

7. The redundant technology infrastructure of claim 1 wherein the primary computer system is further configured to:
receive the computing task; and
redirect the computing task to the digital twin using the physical-virtual connection.

8. The redundant technology infrastructure of claim 1 wherein the physical-virtual connection comprises a plurality of edge-nodes.

9. The redundant technology infrastructure of claim 1 wherein the computing task is a first computing task, the digital twin is further configured to:
compute, based on the state information, a threshold fidelity level for a first subset of the simulated data required to process the first computing task;
based on a time the primary computer system went offline, determine when the first subset of the simulated data will fall below the threshold fidelity level; and
after the first subset of simulated data falls below the threshold fidelity level:
reject a second computing task that requires the first subset of the simulated data to process the second computing task; and
process a third computing task that requires a second subset of the simulated data to process the third computing task.

10. A redundant technology infrastructure comprising:
a primary computer system;
a physical-virtual connection; and
an artificial intelligence (“AI”) engine that is configured to:
capture first state information from the primary computer system using the physical-virtual connection;
construct a first digital twin of the primary computer system based on the first state information;
determine a threshold fidelity level for the first digital twin;
determine a target time when the first digital twin will fall below the threshold fidelity level; and
before the target time, construct a second digital twin based on second state information captured using the physical-virtual connection;
wherein the second digital twin will fall below the threshold fidelity level after the target time.

11. The redundant technology infrastructure of claim 10, wherein the AI engine is further configured to:
detect that the primary computer system is offline;
from an edge node, receive a computing task directed to the primary computer system;
divert the computing task to the first digital twin;
process the computing task using the first digital twin and generate a response to the computing task; and
provide the response to the edge node using a physical-virtual connection.

12. The redundant technology infrastructure of claim 10, wherein the AI engine is configured to construct:
the first digital twin based on capturing state information from the primary computer system at a first twinning rate; and
the second digital twin based on capturing state information from the primary computer system at a second twinning rate.

13. The redundant technology infrastructure of claim 10, wherein the AI engine is configured to:
from an edge node, receive a plurality of computing tasks addressed to the primary computer system;
divert the plurality of computing tasks to the first digital twin;
process the plurality of computing tasks using the first digital twin;
generate performance metrics based on the processing of the plurality of computing tasks by the first digital twin; and
based on the performance metrics, proactively take the primary computer system offline.

14. The redundant technology infrastructure of claim 11, wherein the computing task is a first computing task, while the primary computer system is offline the AI engine is configured to redirect a second computing task to the second digital twin.

15. The redundant technology infrastructure of claim 10, wherein the first state information comprises performance metrics associated with operation of hardware and software components of the primary computer system.

16. The redundant technology infrastructure of claim 15 further comprising a plurality of edge sensors that measure the performance metrics and wherein the performance metrics comprise: memory utilization, central processing unit (CPU) utilization, CPU heat level, disk swap, processing speed, and transmission latency.

17. A method for providing redundant computing processing in response to an infrastructure failure, the method comprising:
using a plurality of edge sensors, capturing performance metrics associated with components of a primary computer system;
constructing a digital twin of the primary computer system based on the performance metrics;
detecting that the primary computer system is offline; and
for a target duration after detecting that the primary computer system is offline:
redirecting a computing task addressed to the primary computer system to the digital twin; and
providing a response to the computing task based on simulated data generated by the digital twin.

18. The method of claim 17 further comprising computing a threshold fidelity level for the simulated data generated by the digital twin;
wherein the target duration corresponds to a period of time starting from the detecting that the primary computer system is offline and ending when the digital twin will fall below the threshold fidelity level.

19. The method of claim 17 wherein the simulated data comprises projected evolution of data generated based on the performance metrics.

20. The method of claim 17 further comprising:
detecting that the primary computer system is online; and
synchronizing one or more data sets stored on the primary computer system based on the simulated data.
